(19) United States
(12) Patent Application Publication
(10) Pub. No.: US 2017/0082563 A1
(43) Pub. Date: Mar. 23, 2017

(54) SYSTEM AND METHODS FOR CHARACTERIZING A SAMPLE BY NMR SPECTROSCOPY

(71) Applicant: President and Fellows of Harvard College, Cambridge, MA (US)

(72) Inventors: Eugene E. Kwan, Cambridge, MA (US); Richard Y. Liu, Toronto (CA)

(73) Assignee: President and Fellows of Harvard College, Cambridge, MA (US)

(21) Appl. No.: 15/268,380

(22) Filed: Sep. 16, 2016

Related U.S. Application Data
(60) Provisional application No. 62/220,340, filed on Sep. 18, 2015.

(51) Int. Cl. G01N 24/08; G01R 33/46

(52) U.S. Cl. CPC G01N 24/087; G01R 33/4625

(57) ABSTRACT

A system for characterizing a sample by NMR spectroscopy is described. The system includes a nuclear magnetic resonance device configured to perform nuclear magnetic resonance spectroscopy on the sample and obtain data indicative of a nuclear magnetic resonance spectrum of the sample. The system also includes circuitry configured to receive the data and compare the data to a prediction for a molecular structure by performing a method according to techniques based on modelling of molecular motion. The method includes identifying shieldings that include rotational and vibrational contributions of the molecular structure. The method further includes constructing the prediction for the molecular structure by incorporating the shieldings as chemical shifts into a nuclear magnetic resonance spectrum of the molecular structure and generating an indication of whether the sample contains the molecular structure by comparing the prediction to the nuclear magnetic resonance spectrum of the sample.

### CROSS REFERENCE TO RELATED APPLICATION

This application claims the benefit of U.S. Provisional Application No. 62/220,340, filed Sep. 18, 2015, which is hereby incorporated by reference to the maximum extent allowable by law.

### BACKGROUND

Field

The present application relates to identifying a molecular structure by using nuclear magnetic resonance (NMR) spectroscopy. NMR spectroscopy is based on measuring the absorption of electromagnetic radiation.

Related Art

NMR spectroscopy is used to characterize the molecular structure of a sample by measuring a spectrum. By identifying the resonant frequencies of the spectrum, the molecular structure of the sample may be inferred.

### BRIEF SUMMARY

Aspects of the present application are directed to systems and methods for characterizing a sample, which include comparing NMR data to a predicted NMR spectrum for a molecular structure. Computational analysis of rotational and vibrational movement of the molecular structure may allow for the construction of an NMR prediction having resonant frequencies sufficient for identification of the molecular structure in the sample.

According to an aspect of the present application, a system for characterizing a sample is provided. The system comprises a nuclear magnetic resonance device configured to perform nuclear magnetic resonance spectroscopy on the sample and obtain data indicative of a nuclear magnetic resonance spectrum for the sample. The system further comprises circuitry configured to receive the data and compare the data to a prediction for a molecular structure by performing a method. The method comprises identifying shieldings that include rotational and vibrational contributions of the molecular structure, constructing the prediction for the molecular structure by incorporating the shieldings as chemical shifts into a nuclear magnetic resonance spectrum of the molecular structure, and generating an indication of whether the sample contains the molecular structure by comparing the prediction to the nuclear magnetic resonance spectrum for the sample.

According to an aspect of the present application, a device for characterizing a sample is provided. The device comprises circuitry configured to receive data indicative of a nuclear magnetic resonance spectrum for the sample and compare the data to a prediction for a molecular structure by performing a method. The method comprises identifying shieldings that include rotational and vibrational contributions of the molecular structure, constructing the prediction for the molecular structure by incorporating the shieldings as chemical shifts into a nuclear magnetic resonance spectrum of the molecular structure, and generating an indication of whether the sample contains the molecular structure by comparing the prediction to the nuclear magnetic resonance spectrum for the sample.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 is a schematic of an exemplary system that performs characterization of a sample, according to some embodiments.

FIG. 2 is a flowchart of an exemplary method for characterizing a sample in accordance with some embodiments.

FIG. 3 is a schematic of exemplary vibrational energy levels for a molecule.

FIG. 4 is a schematic of an exemplary rotational degree of freedom for a molecule.

FIG. 5 is a schematic illustrating arrangements of a molecule arising from rotational and vibrational motion.

FIG. 6 is a schematic illustrating shieldings used to construct a prediction of an NMR spectrum, according to some embodiments.

FIG. 7A depicts schematics of different symmetries for molecule [18]-annulene.

FIG. 7B depicts data comparing stationary and dynamic NMR predictions with experimental data for the molecule [18]-annulene.

FIG. 8 is a table comparing NMR predictions to experimental values for atoms of different molecules.

FIG. 9 is a block diagram of an exemplary computer system on which some embodiments may be implemented.

### DETAILED DESCRIPTION

Aspects of the present application relate to techniques for constructing a prediction of a nuclear magnetic resonance (NMR) spectrum for a molecular structure. The prediction can be used to identify whether the molecular structure is present in a sample by comparing the predicted NMR spectrum to an NMR spectrum of the sample. A sample can be verified as containing a molecule by whether the NMR spectrum of the sample is substantially similar to the predicted NMR spectrum of the molecule. The method used to construct a predicted NMR spectrum for a certain molecule may impact the accuracy in identification of the molecule by NMR spectroscopy. Prediction of an NMR spectrum may include identifying a resonant frequency corresponding to an atomic nucleus of a molecule when a magnetic field is applied.

Resonance occurs when the frequency of the applied magnetic field matches the energy difference between nuclear spin levels of electromagnetic radiation of an atomic nucleus. The local chemical environment of the atomic nucleus may also impact the resonant frequency such that there is a shift in the resonant frequency. Electrons from surrounding atoms in a molecule may create a shielding effect by producing a magnetic field opposite to the magnetic field emitted by the atomic nucleus. In this manner, a resonant frequency corresponding to an atomic nucleus may be considered to have a chemical shift, since the electronic shielding reduces the frequency required to achieve resonance. By incorporating these effects of the local chemical environment into the method for predicting an NMR spectrum, the predicted NMR spectrum may approach the measured NMR spectrum, which may improve identification of a molecule by the predicted NMR spectrum.

One type of method for predicting an NMR spectrum includes determining the resonant frequencies for a stationary molecular structure. A stationary point of a molecular structure may correspond to the molecule's minimum energy geometry. Individual resonant frequencies may be identified by determining, for each atomic nucleus of a molecule, the local chemical effects of surrounding atoms in the molecule having the stationary point geometry. NMR predictions formed for stationary molecular structures by this type of method lack contributions arising from molecular motion, including rotational and vibrational motion. Although a prediction based on a stationary point of a molecular structure may sufficiently distinguish some molecules, as molecules become larger and/or have complex structures, such stationary point predictions may lead to inaccuracy in identification of a sample.

Applicants have appreciated that incorporating contributions arising from molecular motion in determining the resonant frequencies of an NMR spectrum may improve the accuracy of a predicted NMR spectrum. Since a molecule may move by rotation or vibration during an NMR spectroscopy measurement, including contributions from this motion in predicting resonant frequencies may provide a more accurate prediction of an NMR spectrum than considering the minimum energy geometry of the molecule alone. As a molecule rotates and/or vibrates, it explores a number of different geometrical arrangements. For an atomic nucleus of the molecule, the local chemical environment may change as the molecule moves into the different arrangements. A time-averaged shielding can be identified based on the different geometrical arrangements and the local chemical environment of the atomic nucleus in the different arrangements. A predication of an NMR spectrum that includes a resonant frequency based on the time-averaged shielding may more accurately correspond to an experimentally obtained NMR spectrum than an NMR spectrum predicted based on the stationary point of the molecule alone. Accordingly, aspects of the present application relate to constructing a prediction for an NMR spectrum by identifying shieldings that include rotational and/or vibrational contributions for a molecular structure. Characterization of a sample according to the techniques described herein may provide improved accuracy in identification of the molecules present in the sample than is available with other methods for determining a predicted NMR spectrum that do not consider rotational and/or vibration motion.

A predicted NMR spectrum that includes vibrational and rotational motion of the molecule may involve computing multiple geometrical configurations and corresponding shieldings for nuclei in the molecule. However, the ability to efficiently compute the predicted NMR spectrum may limit the implementation of an NMR prediction method for characterization of a sample by an NMR device because of computational demands associated with deriving the NMR prediction. Accordingly, applicants have further appreciated that including techniques that improve computational efficiency and/or reduce computational redundancy in constructing a prediction for an NMR spectrum that is based on molecular motion may ease the implementation of the NMR prediction method in characterizing a sample by an NMR device. Such techniques may include modeling molecular movement of a molecule by initializing multiple instances of the molecule and allowing each instance to run over a period of time to obtain different geometrical arrangements of the molecule rather than using a single instance of the molecule and running it over a longer period of time. Other techniques that may improve computational efficiency may include running the multiple instances of the molecule set by the model in parallel and/or running an instance of the molecule initialized by the model in forward or reverse.

The aspects and embodiments described above, as well as additional aspects and embodiments, are described further below. These aspects and/or embodiments may be used individually, all together, or in any combination of two or more, as the application is not limited in this respect.

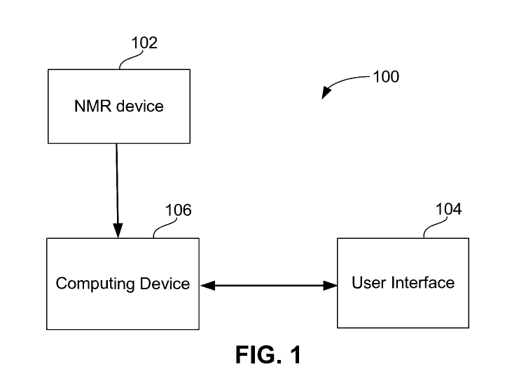

FIG. 1 illustrates an exemplary embodiment of system 100 for characterizing a sample. System 100 includes user interface 104, which may be a component of computing device 106 and/or in communication with computing device 106. System 100 may also include nuclear magnetic resonance (NMR) device 102, which may be in communication with computing device 106. Computing device 106 may include circuitry configured to receive data from NMR device 102 and compare the data to a prediction for a molecular structure. Using techniques described herein, system 100 may analyze a sample by constructing a predicted NMR spectrum and comparing the predicted NMR spectrum to a measured NMR spectrum obtained by NMR device 102.

NMR device 102 may be any suitable nuclear magnetic resonance device. NMR device 102 may be configured to receive a sample, expose the sample to a magnetic field, and measure a response of the sample to the applied magnetic field. Exposing the sample to a magnetic field may lead to splitting of energy levels for certain atomic nuclei of the sample. Resonant absorption of electromagnetic radiation by an atomic nucleus may occur when the frequency of the magnetic field matches the energy difference between the split energy levels for the atomic nuclei. By varying the frequency of the applied magnetic field, NMR device 102 may detect resonant frequencies corresponding to different atomic nuclei of the sample. The chemical environment surrounding an atomic nucleus may impact the resonance frequency of the atomic nucleus. Surrounding atomic nuclei may provide shieldings that are incorporated as chemical shifts in the resulting NMR spectrum. In this manner, although two atomic nuclei may be the same (e.g., carbon nucleus, nitrogen nucleus), the chemical environment for each atomic nucleus may differ, resulting in the resonant frequencies for the two nuclei shifted by a certain amount with respect to each other.

NMR device 102 may detect data indicative of resonant frequencies for a sample. NMR device 102 may output an NMR spectrum, and the NMR spectrum may include resonant frequencies for the sample as peaks in the NMR spectrum. The NMR spectrum may act as a signature for the molecular structure of a molecule and may be used to identify molecules in a sample. One technique used to identify a molecular structure from an NMR spectrum is to compare observed frequencies in the NMR spectrum to frequencies known to correspond to certain atomic nuclei. In some embodiments, identification of a molecular structure may include comparing observed frequencies in an NMR spectrum to known frequencies corresponding to atomic nuclei in certain chemical environments.

Computing device 106 may construct a predicted NMR spectrum for a molecular structure. Computing device 106 may receive information indicative of the molecular structure from a user, such as through user interface 104. Computing device 106 may construct a predicted NMR structure of the molecular structure by determining the resonant frequencies for the atomic nuclei of the molecular structure. As part of constructing a predicted NMR structure, computing device 106 may determine, for an atomic nucleus, an estimate of the chemical environment and its effects on the resonant frequency for the atomic nucleus. By determining a resonant frequency for each atomic nucleus of a molecular structure, a prediction for an NMR spectrum of the molecular structure can be constructed by combining the different resonant frequencies. Computing device 106 may compare resonant frequencies and/or an NMR spectrum received from NMR device 102 with the predicted resonant frequencies and/or NMR spectrum. An indication of whether the sample measured by NMR device 102 includes the molecular structure may be output by computing device 106. In some embodiments, the indication may be transmitted to user interface 104 and presented to a user.

One technique for constructing a prediction for an NMR spectrum of a molecule includes identifying a stationary point of the molecule and determining the resonant frequencies for atomic nuclei of the molecule based on the stationary point arrangement of the molecule. The stationary point may represent a minimum energy geometrical configuration of the molecule.

Since a predicted NMR spectrum based on the stationary point of the molecule lacks contributions from molecular motion, a correction value may be identified to improve the accuracy of the predicted NMR spectrum in representing an experimentally obtained NMR spectrum of the molecule. Accordingly, in some embodiments, computing device 106 may determine a correction value for one or more atomic nuclei of a molecular structure. The correction value may indicate an amount a shielding is offset from its stationary point value. A corrected shielding value may be obtained by adding and/or subtracting the correction value for an atomic nucleus to its stationary point value. The correct shielding value may more accurately reflect the shielding of the atomic nucleus than by a shielding determined from its stationary point alone. By determining correction values for multiple atomic nuclei of a molecule, a prediction of an NMR spectrum for the molecule may represent shieldings for the atomic nuclei that include the correction values.

Some embodiments relate to constructing a prediction for an NMR spectrum of a molecule based on molecular motion of the molecule. Construction of the prediction may include determining different geometrical arrangements of the molecule that may arise from rotational and vibrational motion of the molecule. In some embodiments a surface of a geometrical arrangement may be determined and used to construct a prediction. Shieldings for the atomic nuclei of the molecule identified based on the different geometrical arrangements may be included in a prediction for an NMR spectrum. In some embodiments, a time-averaged shielding for an atomic nucleus determined by averaging the shielding values across the different geometrical arrangements may be included in a prediction for an NMR spectrum.

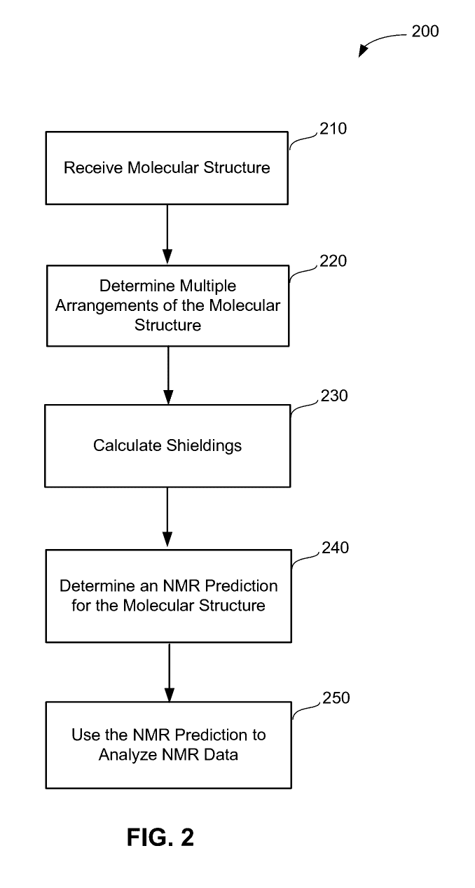

FIG. 2 depicts an exemplary method for characterizing a sample using the techniques described herein, including the system described in FIG. 1. Method 200 begins at act 210 where information about a molecular structure is received, such as by computing device 106 in system 100. Information indicative of a molecule may be received by computing device 106, such as from user interface 104. The information about a molecular structure may include a chemical formula, chemical structure, chemical name, and/or any other suitable type of information used to indicate a specific molecular structure. In some embodiments, computing device 106 determines a minimum energy geometry of the molecule and calculates resonant frequencies based on the minimum energy geometry. In some embodiments, computing device 106 receives information indicative of a minimum energy geometry and/or resonant frequencies calculated from the minimum energy geometry. The minimum energy geometry of the molecule may be considered a stationary point geometry of the molecule.

Multiple geometrical arrangements of the molecular structure are determined by act 220 of method 200. In some embodiments, different geometrical arrangements are determined by modeling molecular motion of the molecular structure. Computing device 106 may include one or more components configured to model molecular motion of a molecule. Computing device 106 may generate data indicative of the molecule undergoing vibrational and rotational molecular motion. Some embodiments relate to determining an initial geometrical arrangement of a molecule and identifying subsequent geometrical arrangements of the molecule based on one or more parameters used to model motion of the molecule by computing device 106. In some embodiments, computing device 106 may determine molecular motion based on a temperature value and/or a size of the molecule. The size of the molecule may identify an axis of inertia of the molecule, which may be used to model molecular motion of the molecule. Accordingly, in some embodiments, computing device 106 may receive as an input, such as from user interface 104, a temperature value and/or data indicative of the molecule's size.

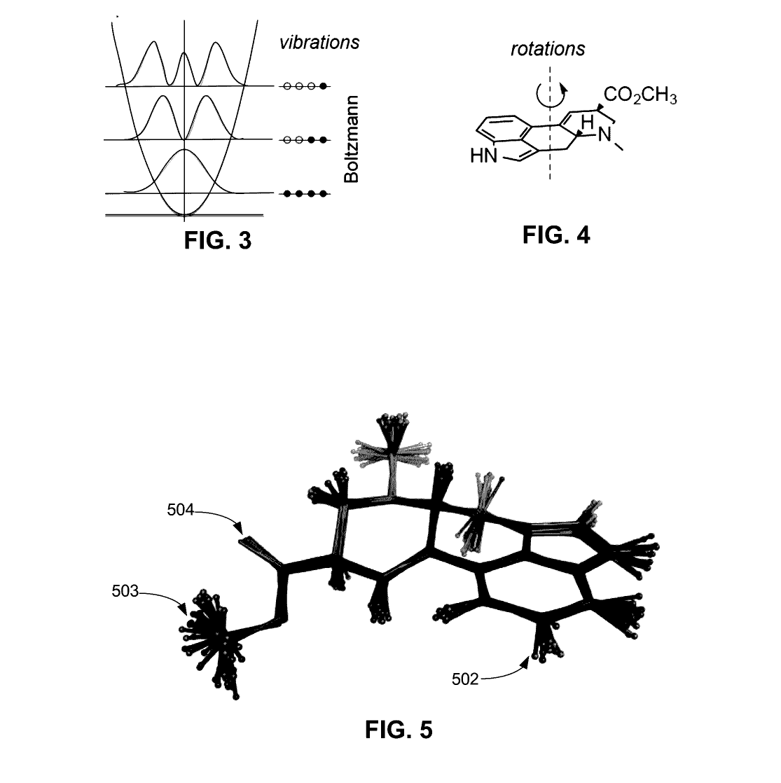

Molecular motion may be determined using principles from quantum mechanics and/or classical mechanics. Computing device 106 may determine information indicative of vibrational molecular motion of the molecule by identifying, for the molecule, one or more eigenstates of a quantum harmonic oscillator corresponding to the molecule. Examples of vibrational eigenstates for a molecule are illustrated in FIG. 3. Computing device 106 may determine information indicative of rotational motion of the molecule by identifying an angular momentum of the molecule. An example of an axis of rotation for a molecule is illustrated in FIG. 4. The data generated by computing device 106 may include information about how the molecule's geometrical arrangement changes as a result of the molecular motion. Trajectories of a molecule and positions of nuclei within the molecule in different geometrical arrangements of the molecule may be determined through classical propagation. In some embodiments, a velocity Verlet scheme may be used to determine the trajectories including using equation x_{t+Δt}=xₜ+υΔt+0.5 αΔt² to identify positions of one or more nuclei of a molecule over time.

An initial geometrical arrangement of a molecule determined by computing device 106 may include identifying parameters based on vibrational and/or rotational molecular motion. Initialization may include determining one or more vibrational energies and/or one or more nuclei displacements of a molecule based on quantum mechanical principles. For example, a vibrational energy and/or positions of nuclei may be selected based on a Boltzmann distribution of different eigenstates. The Boltzmann distribution indicates the relative probabilities of a molecule or atomic nuclei of a molecule being in a certain eigenstate and is defined by a certain temperature value. The temperature value used to define the Boltzmann distribution may be provided as an input to computing device 106. A molecule may have one or more vibrational modes, and an energy level may be randomly selected from a Boltzmann distribution for each of the one or more vibrational modes. In some embodiments, a vibrational mode may be modeled as a simple quantum harmonic oscillator. A displacement along the vibrational mode may be randomly selected according to a displacement-space probability distribution of a simple quantum harmonic oscillator eigenstate of the appropriate energy level determined for the vibrational mode. The initialization process may include providing the molecule with a classical amount of kinetic energy necessary for each vibrational mode based on the identified displacements. The direction of the mode velocities may be sign randomized.

Initialization may include determining one or more rotational energies for the molecule based on classical mechanics. Rotation may be imparted to the entire molecule using a classical initialization scheme. A classical thermal distribution may be determined based on the temperature value. The classical thermal distribution may indicate the relative probabilities of a molecule having certain rotational energies. In some embodiments, the classical thermal distribution may be a Gaussian distribution such that the average rotational energy for an axis is equal to the classical equipartition energy ½ kT. One or more classical thermal distributions may correspond to one or more rotational axes of a molecule. In some embodiments, a rotational velocity is selected for each principal axis of a molecule.

In some embodiments, an initialization process may include selecting at least one vibrational energy and at least one rotational energy and identifying an initial arrangement of a molecule based on the at least one vibrational energy and the at least one rotational energy. The initialization process may be considered a quassiclassical process because it implements principles from both quantum mechanics and classical mechanics. In some embodiments, the at least one vibrational energy may be selected using principles from quantum mechanics and the at least one rotational energy may be selected using the principles of classical mechanics.

Computing device 106 may allow additional geometrical arrangements of a molecule to evolve from an identified initial geometrical arrangement of the molecule. Computing device 106 may determine trajectories of one or more nuclei of the molecule from the initial geometrical arrangement and identify one or more geometrical arrangements based on those trajectories. The trajectories may be determined by identifying positions for one or more nuclei over time. The trajectories may be determined using the principles of classical mechanics (e.g., velocity Verlet scheme). Trajectories may be determined using one or more vibrational energies and one or more rotational energies identified during the initialization process as part of the initial geometrical arrangement. Data indicative of molecular motion of a molecule may be displayed as a movie illustrating the movements a molecule undergoes over time. User interface 106 may include a display and a movie illustrating molecular motion over time may be presented on the display. FIG. 5 depicts multiple frames of an exemplary movie superimposed on each other and illustrates displacements of individual atomic nuclei at different time points for the molecule shown in FIG. 4. As shown in FIG. 5, the atomic nucleus of region 502 corresponding to a hydrogen which undergoes more displacement over time in comparison region the atomic nucleus of region 504 corresponding to an oxygen. Region 503 corresponds to a methyl group of the molecule and may have a larger displacement between different geometrical arrangements of the molecule than other atomic nuclei of the molecule because of its degrees of freedom.

Some embodiments relate to techniques that balance acquiring a sufficient number of geometrical arrangements of molecular structure to provide a desired amount of statistics for a predicted NMR spectrum with computational costs. Determining multiple geometrical arrangements of a molecule may include initializing multiple initial geometrical arrangements and allowing each initial geometrical arrangement to evolve classically using the techniques described herein. In this manner, multiple trajectories or movies of molecular motion may be obtained where each frame includes data indicative of a geometrical arrangement of the same molecule. While increasing the number of trajectories may improve accuracy in a resulting predicted NMR spectrum, there are computational costs associated with initializing and running a movie that may impact efficiency in constructing the predicted NMR spectrum. In addition, determining multiple short trajectories may be more efficient than one long trajectory since the longer trajectory merely re-explores the same phase space while the multiple shorter trajectories explore different initialization parameters. Determining geometrical arrangements by initializing multiple initial geometrical arrangements of a molecule may provide benefits for the operation of computing device 106. Computing device 106 may determine geometrical arrangements in parallel by determining trajectories from each initial geometrical arrangement rather than computing different geometrical arrangements from a single initial geometrical arrangement. In some embodiments, a number of trajectories or instances of determining an initial geometrical arrangement and a trajectory from the initial arrangement may be identified to balance both a desired level of accuracy and computational efficiency. The number of trajectories may be approximately 25, approximately 100, approximately 200, approximately 300, or approximately 400. The number of trajectories may be in the range of 25 to 500, or any value or range of values within that range.

The length of a trajectory from an initial arrangement may determine the number of geometrical arrangements determined from an initial arrangement and provide a sufficient number of geometrical arrangements to determine a predicted NMR spectrum with a desired level of accuracy. Some embodiments include initializing multiple movies where each movie has a desired number of frames corresponding to the length of the trajectory from an initial geometrical arrangement. Since accuracy may reduce as the number of trajectories becomes large allowing for propagation of error as the model is run for longer time periods, the number of trajectories from an initial arrangement may be selected to achieve an overall level of accuracy in obtaining different geometrical arrangements of a molecule. The length of a trajectory may be approximately 125 points, approximately 150 points, approximately 250 points, or approximately 350 points. The length of a trajectory may be in the range of 100 to 500 points, or any value or range of values within that range. In some embodiments, the interval between time points in a trajectory may correspond to a time interval (e.g., one femtosecond). In such embodiments, the length of a trajectory may be approximately 150 fs, approximately 250 fs, or approximately 350 fs. The length of a trajectory may be in the range of 100 fs to 500 fs, or any value or range of values within that range.

Some embodiments relate to modeling molecular motion from an initial geometrical arrangement in directions corresponding to time moving forward (e.g., positive time value time) and time moving in revers (e.g., negative time value). Once an initial geometrical arrangement is determined, a trajectory may be calculated by allowing the initial geometrical arrangement to evolve over time proceeding in a forward direction and another trajectory may be calculated by allowing the initial geometrical arrangement to evolve over time proceeding in a reverse direction. A forward direction in time may correspond to inputs in the model indicating that time proceeds in a positive direction, while a reverse direction in time may correspond to inputs in the model indicating that time proceeds in a negative direction. Obtaining both a forward trajectory and a reverse trajectory may improve computational efficiency of computing device 106 in calculating a predicted NMR spectrum by reducing the computational costs associated with computing an initial geometrical arrangement and initialization parameters of a molecule since a single initialization process is used to obtain two trajectories. In some embodiments, a forward trajectory and a reverse trajectory are combined to form a single trajectory indicating motion of a molecule.

Method 200 includes calculating shieldings for the multiple geometrical arrangements of a molecular structure by act 230. Some embodiments relate to calculating shieldings for a portion of the geometrical arrangements determined by a trajectory. Although geometrical arrangements of a molecule are determined for different time points within a trajectory, shieldings may be calculated for only arrangements at a certain interval within the trajectory, according to some embodiments. Selecting arrangements at a certain time interval may reduce computational costs associated with determining the resulting predicted NMR spectrum without reducing the accuracy of the prediction. In some embodiments, shieldings are calculated for geometrical arrangements at an interval of approximately 4 time points, approximately 8 time points, approximately 12 time points. An interval for calculating shieldings may be in the range of 4 time points to 16 time points, or any value or range of values within that range.

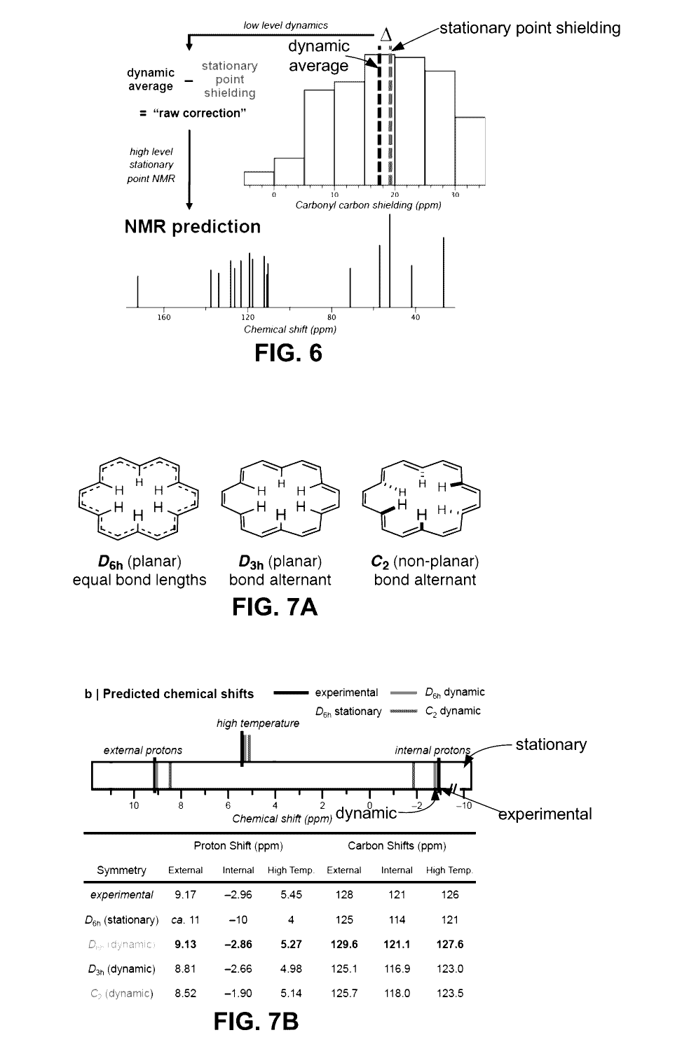

The data may be used to determine a prediction of an NMR spectrum of the molecular structure by act 240. Constructing a predicted NMR spectrum of the molecule may include determining how the different geometrical structures impact an NMR spectrum in comparison to an NMR spectrum determined by the stationary point of the molecule alone. Constructing the prediction for the molecular structure may include incorporating the shieldings determined by the different geometrical arrangements as chemical shifts into a nuclear magnetic resonance spectrum of the molecular structure. The shieldings calculated for a molecule based on the different geometrical structures may provide one or more resonant frequencies of the molecule. An NMR spectrum may be predicted from the one or more resonant frequencies. In some embodiments, one or more chemical shifts are calculated from the shieldings. A chemical shift may provide a correction value for one or more resonant frequencies of a stationary point for the molecule. Constructing a predicted NMR spectrum may include combining the one or more chemical shifts with information from the stationary point geometry of the molecule. In some embodiments, an average value for a shielding determined from multiple geometrical arrangements may be used to construct a prediction for an NMR spectrum. The average value may be obtained by determining a shielding value for each geometrical arrangement from among multiple geometrical arrangements and calculating an average value from the multiple shielding values. A correction value may be obtained by identifying a difference between the average shielding value and a shielding value from a stationary point geometry of the molecule. The correction value may correspond to a chemical shift, and a predicted NMR spectrum may be obtained by applying the correction value to an NMR spectrum determined by the stationary point geometry. FIG. 6 illustrates a schematic for an exemplary process where a correction value or “raw correction” equals the difference between a dynamic average shielding value and a stationary point shielding value. The correction value is applied to a stationary point NMR spectrum to construct an NMR spectrum prediction because the shielding correction value corresponds to one or more chemical shifts for the NMR prediction.

A prediction of an NMR spectrum according to the techniques described herein may more accurately reflect experimental NMR data than a predicted NMR spectrum based on stationary point geometry alone. For example, molecule [18]-annulene may have different symmetry configurations (D₆ₕ, D₃ₕ, and C₂) shown in FIG. 7A. FIG. 7B illustrates data for proton chemical shifts and carbon chemical shifts for experimental NMR data in addition to data for predictions based on stationary D₆ₕ symmetry and dynamic D₆ₕ symmetry that includes information about molecular motion. As shown both in the graph and table of FIG. 7B, the dynamic D₆ₕ symmetry chemical shifts are closer to the experimental data than stationary D₆ₕ symmetry chemical shifts. As an example, comparing data for internal shifts, the experimentally obtained NMR data has a shift at −2.96 ppm while dynamic D₆ₕ symmetry data has a shift at −2.86 ppm and is substantially closer than stationary D₆ₕ symmetry data, which has a shift at −10 ppm. These results provide an indication that including molecular motion in a prediction for NMR data by modeling both rotational and vibrational data can lead to improved accuracy in the NMR prediction corresponding to experimental NMR data.

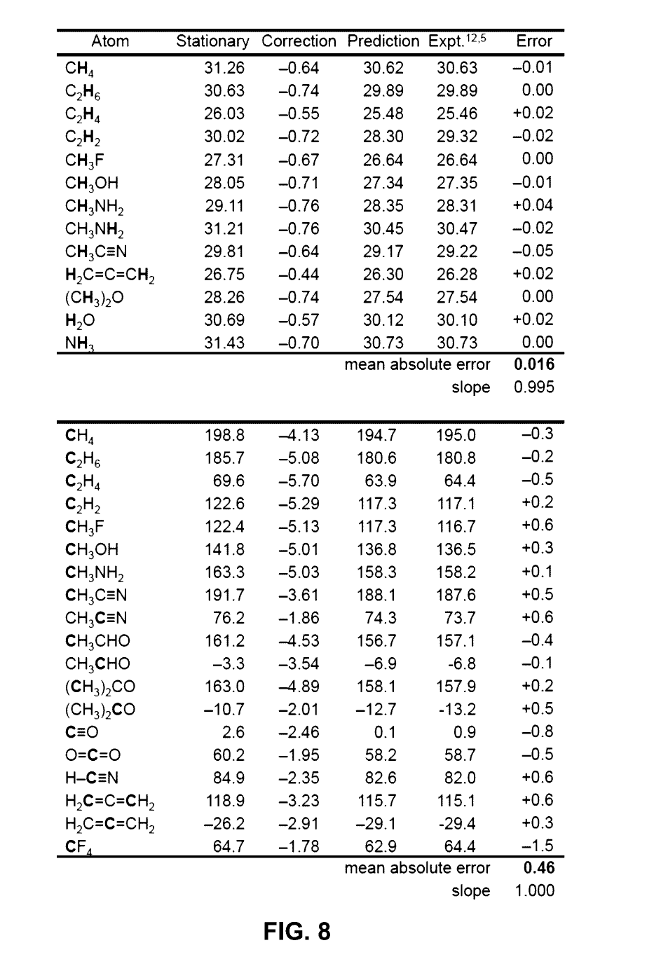

The techniques described herein can be applied to different types of molecules. In some embodiments, these techniques may provide improved NMR predictions for larger molecules (e.g., molecules having ten or more atoms). FIG. 8 depicts a table of data comparing NMR experimental data with predicted NMR data for different atoms in molecules where the atom corresponding to the data in the row of the table is indicated in bold. Data for the proton chemical shifts is shown in the upper table, and data for carbon chemical shifts is shown in the lower table. For each row corresponding to an atomic nucleus, a correction value determined by modeling the molecular motion of the molecule is shown and a prediction value is determined by summing the correction value and the stationary point value. An error value corresponds to the difference between the predicted value and the experimental value. As shown in the table of FIG. 8, the experimental data is closer in value to the predicted values than the stationary values, illustrating that adding the correction value to the stationary value improves the accuracy of the resulting prediction.

The improved accuracy of a prediction based on molecular motion in addition to stationary point geometry of a molecule may allow for identification of more complex and/or larger molecules than a prediction based on stationary point geometry alone. In some embodiments, the techniques described herein may provide a sufficient level of accuracy for constructing a prediction of an NMR spectrum of a molecule having at least ten heavy atoms.

The predicted NMR spectrum can be used to analyze NMR data by act 250. In some embodiments, a user may provide as input information indicative of one or more molecular structures as a potential candidate (e.g., guess) for a sample measured by NMR device 102. The information may be provided by a user via user interface 104. Computing device 106 may determine a predicted NMR spectrum for each of the one or more molecular structures and compare the predicted NMR spectra to an experimental NMR spectrum based on data received from NMR device 102. Computing device 106 may determine a comparison value indicating the extent to which a predicted NMR spectrum matches an experimental NMR spectrum. Comparison values may be determined for multiple predictions of different molecular structures. In some embodiments, a comparison value may include a degree of certainty that the sample measured by NMR device 102 contains a certain molecular structure based on comparing the prediction for the molecular structure with the NMR data obtained by NMR device 102.

An indication of the comparison values and associated molecular structures may be generated by computing device 106. The indication may be received by user interface 104 and presented to a user. The indication may include information about whether a sample contains a molecular structure based on comparing a prediction of the molecular structure to an NMR spectrum of the sample. The indication may be generated based on a degree of certainty that the sample contains a certain molecular structure, such as whether the degree of certainty is above or below a threshold value. User interface 104 may be configured to present the indication to a user. User interface 104 may present to a user an indication of whether the sample contains a molecular structure. User interface 104 may present to the user a degree of certainty that the sample contains the molecular structure. An indication presented to a user may include a degree of certainty that the sample contains a molecular structure. In some embodiments, computing device 106 may provide an indication of a molecular structure having a predicted NMR spectrum that matches the experimental NMR data above a certain degree of certainty. In this manner, a sample may be characterized by identifying a molecular structure having a predicted NMR spectrum that approximates an experimental NMR spectrum of the sample.

Various computational methods may be employed in predicting an NMR spectrum of a molecule. Methods may include modelling methods that employ quantum mechanical principles, including density functional theory (DFT). Some embodiments relate to implementing Hartree-Fock methods, Møller-Plesset perturbation methods (e.g., MP2), hybrid functional methods (e.g., B3LYP, PBEO), and/or M06 functional methods (e.g., M06-2X). More than one computational method may be combined as a composite method. Gaussian models may incorporate one or more basis sets (e.g., 6-31G(d), cc-pVDZ, MIDI!, cc-PVDZ, cc-pVTZ, pcS-2, pcS-3). Techniques for computational modeling may be used to determine a stationary point geometry, a potential energy surface of a geometrical arrangement of a molecule, positions of atomic nuclei in a molecule, forces on a molecule while it undergoes molecular motion, and/or NMR data (e.g., shieldings, chemical shifts). As an example, a stationary point geometry may be determined by computational methods B3LYP/cc-pVDZ, B3LYP/cc-pVTZ, and B3LYP/jul-cc-pVTZ NMR. Forces on a molecule may be calculated at each point of the molecule by using computational methods based on B3LYP/MIDI!. Methods for calculating shieldings may include Gauge-Including Atomic Orbital (GIAO) computational techniques. In some embodiments, shieldings can be calculated using the GIAO scheme at B3LYP/cc-pVDZ.

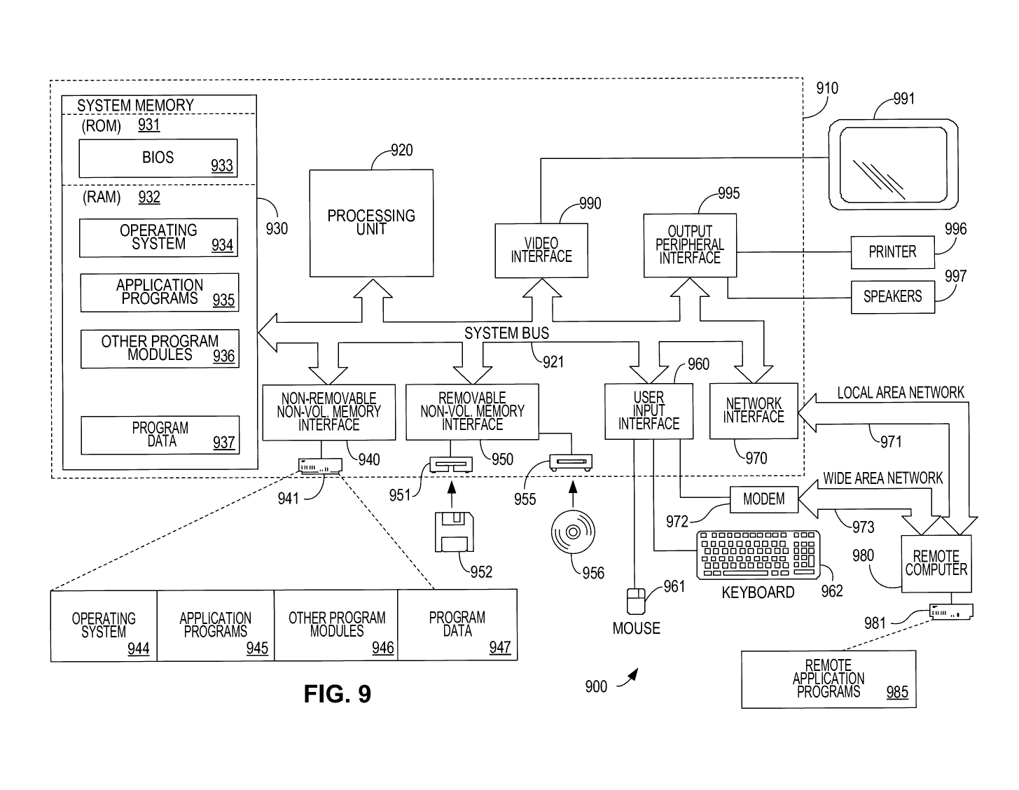

A computing system in accordance with the techniques described herein may take any suitable form, as embodiments are not limited in this respect. An illustrative implementation of a computer system that may be used in connection with some embodiments is shown in FIG. 9. One or more computer systems such as computer system 900 may be used to implement any of the functionality described above. A computing system may have some or all of the components illustrated in FIG. 9.

A device that a consumer may use to perform functions such as accessing information stored on the server and placing an order may be any suitable device having a user interface to accept input form the consumer. An illustrative implementation of a computer system that may be used as a consumer device with some embodiments is shown in FIG. 9. A consumer device may have some or all of the components illustrated in FIG. 9.

FIG. 9 illustrates an example of a suitable computing system environment 900 on which the embodiments may be implemented. The computing system environment 900 is only one example of a suitable computing environment and is not intended to suggest any limitation as to the scope of use or functionality of the invention. Neither should the computing environment 900 be interpreted as having any dependency or requirement relating to any one or combination of components illustrated in the exemplary operating environment 900.

The embodiments are operational with numerous other special purpose computing system environments or configurations. Examples of well-known computing systems, environments, and/or configurations that may be suitable for use with the embodiments include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like.

The computing environment may execute computer-executable instructions, such as program modules. Generally, program modules include routines, programs, objects, components, data structures, etc. that perform particular tasks or implement particular abstract data types. The embodiments may also be practiced in distributed computing environments where tasks are performed by remote processing devices that are linked through a communications network. In a distributed computing environment, program modules may be located in both local and remote computer storage media including memory storage devices.

With reference to FIG. 9, an exemplary system for implementing the embodiments include a general purpose computing device in the form of a computer 910. Components of computer 910 may include, but are not limited to, a processing unit 920, a system memory 930, and a system bus 921 that couples various system components including the system memory to the processing unit 920. The system bus 921 may be any of several types of bus structures including a memory bus or memory controller, a peripheral bus, and a local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as Mezzanine bus.

Computer 910 typically includes a variety of computer readable media. Computer readable media can be any available media that can be accessed by computer 910 and includes both volatile and nonvolatile media, removable and non-removable media. By way of example, and not limitation, computer readable media may comprise computer storage media and communication media. Computer storage media includes both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can accessed by computer 910. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be considered to be within the scope of computer readable media.

The system memory 930 includes computer storage media in the form of volatile and/or nonvolatile memory such as read only memory (ROM) 931 and random access memory (RAM) 932. A basic input/output system 933 (BIOS), containing the basic routines that help to transfer information between elements within computer 910, such as during start-up, is typically stored in ROM 931. RAM 932 typically contains data and/or program modules that are immediately accessible to and/or presently being operated on by processing unit 920. By way of example, and not limitation, FIG. 9 illustrates operating system 934, application programs 935, other program modules 936, and program data 937.

The computer 910 may also include other removable/non-removable, volatile/nonvolatile computer storage media. By way of example only, FIG. 9 illustrates a hard disk drive 941 that reads from or writes to non-removable, nonvolatile magnetic media, a magnetic disk drive 951 that reads from or writes to a removable, nonvolatile magnetic disk 952, and an optical disk drive 955 that reads from or writes to a removable, nonvolatile optical disk 956 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 941 is typically connected to the system bus 921 through an non-removable memory interface such as interface 940, and magnetic disk drive 951 and optical disk drive 955 are typically connected to the system bus 921 by a removable memory interface, such as interface 950.

The drives and their associated computer storage media discussed above and illustrated in FIG. 9, provide storage of computer readable instructions, data structures, program modules and other data for the computer 910. In FIG. 9, for example, hard disk drive 941 is illustrated as storing operating system 944, application programs 945, other program modules 946, and program data 947. Note that these components can either be the same as or different from operating system 934, application programs 935, other program modules 936, and program data 937. Operating system 944, application programs 945, other program modules 946, and program data 947 are given different numbers here to illustrate that, at a minimum, they are different copies. A user may enter commands and information into the computer 910 through input devices such as a keyboard 962 and pointing device 961, commonly referred to as a mouse, trackball or touch pad. Other input devices (not shown) may include a microphone, joystick, game pad, satellite dish, scanner, or the like. These and other input devices are often connected to the processing unit 920 through a user input interface 960 that is coupled to the system bus, but may be connected by other interface and bus structures, such as a parallel port, game port or a universal serial bus (USB). A monitor 991 or other type of display device is also connected to the system bus 921 via an interface, such as a video interface 990. In addition to the monitor, computers may also include other peripheral output devices such as speakers 997 and printer 996, which may be connected through a output peripheral interface 995.

The computer 910 may operate in a networked environment using logical connections to one or more remote computers, such as a remote computer 980. The remote computer 980 may be a personal computer, a server, a router, a network PC, a peer device or other common network node, and typically includes many or all of the elements described above relative to the computer 910, although only a memory storage device 981 has been illustrated in FIG. 9. The logical connections depicted in FIG. 9 include a local area network (LAN) 971 and a wide area network (WAN) 973, but may also include other networks. Such networking environments are commonplace in offices, enterprise-wide computer networks, intranets and the Internet.

When used in a LAN networking environment, the computer 910 is connected to the LAN 971 through a network interface or adapter 970. When used in a WAN networking environment, the computer 910 typically includes a modem 972 or other means for establishing communications over the WAN 973, such as the Internet. The modem 972, which may be internal or external, may be connected to the system bus 921 via the user input interface 960, or other appropriate mechanism. In a networked environment, program modules depicted relative to the computer 910, or portions thereof, may be stored in the remote memory storage device. By way of example, and not limitation, FIG. 9 illustrates remote application programs 985 as residing on memory device 981. It will be appreciated that the network connections shown are exemplary and other means of establishing a communications link between the computers may be used.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of” and “consisting essentially of” shall be closed or semi-closed transitional phrases, respectively.

What is claimed is:

1. A system for characterizing a sample, the system comprising:
a nuclear magnetic resonance device configured to perform nuclear magnetic resonance spectroscopy on the sample and obtain data indicative of a nuclear magnetic resonance spectrum for the sample; and
circuitry configured to receive the data and compare the data to a prediction for a molecular structure by performing a method comprising:
identifying shieldings that include rotational and vibrational contributions of the molecular structure;
constructing the prediction for the molecular structure by incorporating the shieldings as chemical shifts into a nuclear magnetic resonance spectrum of the molecular structure; and
generating an indication of whether the sample contains the molecular structure by comparing the prediction to the nuclear magnetic resonance spectrum for the sample.

2. The system of claim 1, wherein identifying the shieldings comprises modeling the molecular structure to determine a plurality of geometrical arrangements for the molecular structure.

3. The system of claim 2, wherein a geometrical arrangement of the plurality of geometrical arrangements is based on at least one rotational degree of freedom for the molecular structure.

4. The system of claim 2, wherein a structural arrangement of the plurality of geometrical arrangements is based on at least one vibrational degree of freedom for the molecular structure.

5. The system of claim 2, wherein identifying the shieldings comprises determining, for the plurality of geometrical arrangements, a time-average shielding for the molecular structure.

6. The system of claim 5, wherein identifying the shieldings comprises determining a difference between the time-averaged shielding for the molecular structure and a stationary point shielding for the molecular structure.

7. The system of claim 1, wherein generating the indication comprises determining a degree of certainty that the sample contains the molecular structure.

8. The system of claim 1, further comprising a user interface configured to receive a user input indicative of the molecular structure from a user.

9. The system of claim 1, further comprising a user interface configured to present the indication of whether the sample contains the molecular structure to a user.

10. The system of claim 9, wherein presenting the indication to the user comprises presenting a degree of certainty that the sample contains the molecular structure.

11. A device for characterizing a sample, the apparatus comprising:
circuitry configured to receive data indicative of a nuclear magnetic resonance spectrum for the sample and compare the data to a prediction for a molecular structure by performing a method comprising:
identifying shieldings that include rotational and vibrational contributions of the molecular structure;
constructing the prediction for the molecular structure by incorporating the shieldings as chemical shifts into a nuclear magnetic resonance spectrum of the molecular structure; and
generating an indication of whether the sample contains the molecular structure by comparing the prediction to the nuclear magnetic resonance spectrum for the sample.

12. The device of claim 11, wherein identifying the shieldings comprises modeling the molecular structure to determine a plurality of geometrical arrangements for the molecular structure.

13. The device of claim 12, wherein a geometrical arrangement of the plurality of geometrical arrangements is based on at least one rotational degree of freedom for the molecular structure.

14. The device of claim 12, wherein a structural arrangement of the plurality of geometrical arrangements is based on at least one vibrational degree of freedom for the molecular structure.

15. The device of claim 12, wherein identifying the shieldings comprises determining, for the plurality of geometrical arrangements, a time-average shielding for the molecular structure.

16. The device of claim 15, wherein identifying the shieldings comprises determining a difference between the time-averaged shielding for the molecular structure and a stationary point shielding for the molecular structure.

17. The device of claim 11, wherein generating the indication comprises determining a degree of certainty that the sample contains the molecular structure.

18. The device of claim 11, further comprising a user interface configured to receive a user input indicative of the molecular structure from a user.

19. The device of claim 11, further comprising a user interface configured to present the indication of whether the sample contains the molecular structure to a user.

20. The device of claim 19, wherein presenting the indication to the user comprises presenting a degree of certainty that the sample contains the molecular structure.
